(19) United States
(12) Patent Application Publication
(10) Pub. No.: US 2026/0305456 A1
(43) Pub. Date: Oct. 1, 2026

(54) MICROELECTRONIC DEVICE PACKAGE WITH OPEN CAVITY

(71) Applicant: Texas Instruments Incorporated, Dallas, TX (US)

(72) Inventor: Masamitsu Matsuura, Oita (JP)

(21) Appl. No.: 19/096,644

(22) Filed: Mar. 31, 2025

(51) Int. Cl. H01L 23/31; H01L 21/56; H01L 21/77; H01L 23/00; H01L 23/495

(52) U.S. Cl. CPC H10W 74/137; H10D 84/01; H10W 70/465; H10W 74/014; H10W 74/016; H10W 74/141; H10W 72/075; H10W 72/07521; H10W 72/07533; H10W 72/07553; H10W 72/531; H10W 74/10; H10W 90/756

(57) ABSTRACT

An apparatus includes: a sensor die having a layer of sense material on a device side surface, and having bond pads on the device side surface; a mold wall formed over a central portion of the device side surface, the mold wall defining an open cavity over a portion of the sense material; the sensor die mounted on a device mounting surface of a package substrate, the package substrate having leads spaced from the device mounting surface; electrical connections coupling bond pads of the sensor die to the leads of the package substrate; and mold compound covering a portion of the sensor die, the electrical connections, and a portion of the leads, the mold compound forming a body of a microelectronic device package, wherein the portion of the sensor die within the open cavity formed by the mold wall is exposed from the body of the microelectronic device package.

### TECHNICAL FIELD

This disclosure relates generally to microelectronic device packages, and more particularly to microelectronic device packages with an open cavity for a sensor.

### BACKGROUND

Processes for producing microelectronic device packages include mounting one or more semiconductor dies to a package substrate and subsequently covering the electronic devices with a dielectric material, such as a mold compound, to form packaged microelectronic devices. In certain applications, a sensor die is packaged. In order to expose a sense material layer to the atmosphere, an open cavity is formed in the mold compound that forms the body for the microelectronic device package. Sense material on the sensor die can be exposed by the open cavity.

In a prior approach, customized mold tools are used to mold the package for the sensor die after the die is mounted to a package substrate. At the molding stage, the die is mounted by a die attach material to a die mounting portion of the package substrate, for example a die pad of a leadframe. The mold tool has protrusions corresponding to the position of the open cavity for each sensor die. The molding process can be film assisted, where a film is placed in the mold tool prior to molding, the film is conformally positioned using a vacuum.

During device package molding, inconsistent results for the dimensions of the open cavity sometimes occur. The sensor dies are mounted on a package substrate, such as a leadframe, by a thin layer of die attach material. During molding, in order to form a cavity extending into the mold compound and exposing the surface of the sensor die, the sensor dies are contacted by the protrusions in the mold tool. Contact to the die by the mold tool can cause die tilt, which can affect the die and the completed package, so that the package has a defective shape for the open cavity. A risk of a die crack defect also increases. The need for a custom mold tool for each type of sensor die to be packaged creates the need for mold tool manufacturing, inventory control, and tracking various mold tools, increasing costs. The die tilt defects, die crack risks, and inconsistent open cavity shapes result in scrapped devices, reducing yields and increasing the costs for the packaged devices.

A continuing need thus exists for robust and economical microelectronic device packages with open cavities, and methods for making these microelectronic device packages.

### SUMMARY

In a described example, a method includes: forming sensor dies on a substrate, each sensor die having a layer of sense material on a device side surface; forming mold walls over the sensor dies on the substrate, the mold walls extending across a central portion of a corresponding sensor die, the mold walls defining an open cavity over a portion of the sense material on the corresponding sensor dies; singulating the sensor dies from the substrate into unit sensor dies, each unit sensor die having the corresponding mold wall over the device side surface of the unit sensor die; mounting a unit sensor die on a device mounting portion of a package substrate, the package substrate having leads spaced from the device mounting portion; forming electrical connections between bond pads on the unit sensor die and the leads of the package substrate; and covering a portion of the sensor die, the electrical connections, and a portion of the leads with mold compound, the mold compound forming a body of a microelectronic device package, the portion of the unit sensor die within the open cavity defined by the mold wall exposed from the body of the microelectronic device package.

In an additional described example, a method includes: forming sensor dies on a substrate, the sensor dies comprising a polymer dielectric on a device side surface of the sense dies; forming mold walls over the sensor dies on the substrate, the mold walls extending across a central portion of corresponding sensor dies, the mold walls defining an open cavity over a portion of the polymer dielectric material on the corresponding sensor dies; singulating the sensor dies from the substrate into unit sensor dies, each unit sensor die having the corresponding mold wall over the device side surface of the unit sensor die; mounting a unit sensor die on a die pad of a leadframe, the leadframe having leads spaced from the die pad; forming wire bonds between bond pads on the unit sensor die and the leads of the package substrate; and covering a portion of the sensor die, the wire bonds, and a portion of the leads with mold compound, the mold compound forming a body of a microelectronic device package, the portion of the unit sensor die within the open cavity formed by the mold wall exposed from the body of the microelectronic device package.

In an additional described example, an apparatus includes: a sensor die having a layer of sense material on a device side surface, and having bond pads on the device side surface; a mold wall formed over a central portion of the device side surface, the mold wall defining an open cavity over a portion of the sense material; the sensor die mounted on a device mounting surface of a package substrate, the package substrate having leads spaced from the device mounting surface; electrical connections coupling bond pads of the sensor die to the leads of the package substrate; and mold compound covering a portion of the sensor die, the electrical connections, and a portion of the leads, the mold compound forming a body of a microelectronic device package, wherein the portion of the sensor die within the open cavity formed by the mold wall is exposed from the body of the microelectronic device package.

In a further described example, a microelectronic device package with an open cavity includes: a sensor die having a layer of sense material on a device side surface; a mold wall formed over a central portion of the device side surface of the sensor die, the mold wall defining the open cavity over a portion of the sense material; the sensor die mounted on a die pad of a leadframe, the leadframe having leads spaced from the device mounting surface; wire bond connections formed between the bond pads of the sensor die and the leads of the leadframe; and mold compound covering a portion of the sensor die, the wire bonds, and a portion of the leads, the mold compound forming the body of the microelectronic device package, wherein the portion of the sensor die within the open cavity formed by the mold wall is exposed from the body of the microelectronic device package.

### BRIEF DESCRIPTION OF THE DRAWINGS

FIG. 1 illustrates, in a projection view, a microelectronic device package including an example arrangement.

FIG. 2 illustrates, in a cross-sectional view, the microelectronic device package of the arrangement of FIG. 1.

FIGS. 3A-3B illustrate, in a projection view and a close-up projection view, respectively, semiconductor dies on a semiconductor wafer and an individual semiconductor die from the semiconductor wafer.

FIGS. 4A-4F illustrate, in a series of cross-sectional views, selected steps for forming a sensor die of an example arrangement.

FIG. 5 illustrates, in a flow diagram, selected steps of a method for forming a microelectronic device package of an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “die” is used herein. A “die” is a unit device fabricated on a substrate in a group or gang manufacturing operation. In an example process, the substrate can be a semiconductor substrate, such as a silicon wafer. Dies are manufactured on semiconductor wafers in wafer manufacturing facilities, or “fabs.” The dies produced are then semiconductor dies. However, in some example arrangements, certain dies for sensors can be formed on other types of substrates, such as glass or ceramic. The term sensor die is therefore used, which can be formed on a substrate that is a semiconductor wafer, or which can be formed on another type of substrate.

The term “semiconductor die” is used herein. A semiconductor die can be a discrete semiconductor device such as a bipolar transistor, a few discrete devices such as a pair of power field effect transistor (“FET”) switches fabricated together on a single semiconductor die, or a semiconductor device can be an integrated circuit with multiple semiconductor devices such as the multiple capacitors in an A/D converter. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device. When semiconductor devices are fabricated contemporaneously on a semiconductor wafer and then individually separated from the semiconductor wafer, the individual units are referred to as “semiconductor dies.” A semiconductor die is also a semiconductor device. In an example arrangement, a sensor die can be a semiconductor die, the sensor die is packaged in a microelectronic device package with an open cavity. In alternative arrangements, a sensor die can be formed on a substrate other than a semiconductor substrate, and the sensor die is then not a semiconductor die in those arrangements. In addition to the sensor die, other components including additional semiconductor dies and passive components can be included in the microelectronic device package. Multi-chip modules (“MCM”) and system in package (“SIP”) devices can be formed in the microelectronic device packages.

The term “passive component” is used herein. As used herein, a passive component is a component without active devices, for example, a resistor, capacitor, inductor, coil, diode, or sensor.

Sensor dies of various types can be used in the arrangements. In an example arrangement, a relative humidity sensor uses a polymer with a dielectric constant that varies with relative humidity in a predictable way. The polymer can be used as the dielectric for a capacitor with conductive plates formed over opposing sides of the dielectric. In another example sensor useful with the arrangements, a metal oxide gas sensor is formed as a sensor die. The metal oxide gas sensor includes a sensor material layer of metal oxide material. In examples useful with the arrangements, a metal oxide layer of tin oxide, zinc oxide, titanium oxide or cobalt oxide can be used.

Electrodes are formed within or adjacent the metal oxide material, the electrodes can be used to sense changes in resistivity in the metal oxide material. For a gas sensor application using the metal oxide sensor material, heater conductors are also fabricated in dielectric material positioned beneath the metal oxide layer. In operation, when the layer of metal oxide is heated to an elevated temperature and then exposed to an oxidizing gas which increases the oxygen at the surface of the metal oxide layer, the resistance of the metal oxide layer increases. The resistance change can be detected using sense electrodes, and the change can be used to detect oxidizing gas. In another application, when the metal oxide layer is heated to an operation temperature and then exposed to a volatile organic compound (“VOC”), the oxygen is reduced at the surface of the metal oxide layer, the resistance again changes, now decreasing, and using the sense electrodes, the change can be detected, indicating the presence of a VOC gas. An example of VOC gas that can be detected is ethanol. Metal oxide layers for use in metal oxide sensors can include SnO₂, ZnO, TiO₂, CoO, and other metal oxides. Gases that can be detected include nitrogen, hydrogen, carbon monoxide, carbon dioxide and various VOC gases.

Other types of sensors useful in the arrangements include a sensor material layer to sense changes in conditions. Examples include acoustic wave sensors, which can use aluminum nitride (AlN) layers, for example, to sense certain conditions. Acoustic wave material uses a piezoelectric material that changes electrically in a predictable way with pressure, stress, or strain, for example. Conductors in interdigitated patterns can be formed either within (for bulk acoustic wave sensors) or on (for surface acoustic wave sensors) the aluminum nitride layer, which is a polycrystalline layer. A signal that has a frequency can be applied to the polycrystalline layer, the frequency or amplitude of the signal (for example, an acoustic wave) will change in response to certain conditions, forming the sensor. Other examples can include photosensors, temperature, relative humidity sensors as described above, and acoustic sensors. Liquid sensors can be used to detect carbonation levels or concentrations in liquids. Water/moisture/rainfall sensors can be formed using conductors that are spaced apart by a dielectric, the water providing a conductive path between the electrodes on the sensor layer which can close an electronic circuit and thereby provide a signal. Temperature, pressure, humidity, liquid, light, gas, and sound are all physical properties that can be sensed using a sensor with an open cavity in a microelectronics device package such as is provided in the arrangements.

In the arrangements, in operation, the sensor material is exposed to the ambient atmosphere. A microelectronic device package for the sensor can have an open cavity in the package body that exposes at least a portion of the sensor material layer, so that the atmosphere, light, sound, liquid, or gas being sensed is in contact with the sensor material layer. In an example using a polymer dielectric to sense humidity, the microelectronic device package exposes the sensor material to the atmosphere in the cavity opening in the package body. A polyimide can be used as the polymer dielectric. A capacitor sensor can be formed using the polymer dielectric between capacitive plates, the capacitance changing with relative humidity. In the arrangements, the package body can be formed using a mold compound. In one example approach for a sensor application, during molding an opening is formed on one surface of the molded package that is aligned with and exposes a portion of the sensor material layer on the surface of the sensor die.

The term “microelectronic device package” is used herein. As used herein, a microelectronic device package has at least one die electrically coupled to terminals and has a package body that protects and covers the at least one semiconductor die. The microelectronic device package can include additional semiconductor dies or additional elements. In some examples, wire bonds can be used to form electrical connections. Ribbon bonds can also be used.

The term “package substrate” is used herein. A package substrate is a substrate arranged to receive a die such as a sensor die, and optionally other components, and to support the sensor die in a completed microelectronic device package. Package substrates useful with the arrangements include leadframes, molded interconnect substrates (MIS), partially etched leadframes, pre-molded leadframes (PMLFs), embedded trace substrates (ETS), and multilayer package substrates. Additive manufacturing using build up material can be used to form a package substrate. For example, a laminated multilayer package substrate can be formed using layers of Ajinomoto Build Up Film (“ABF”) and plating conductors between dielectric layers in a repetitive additive process. In an example arrangement, the package substrate can be a leadframe. Certain leads of the package substrate are configured as terminals of the microelectronic device package by exposing portions of the leads from the mold compound.

In packaging semiconductor dies or sensor dies, mold compound may be used to partially cover a package substrate, to entirely cover the package substrate, to cover passive components, to cover semiconductor dies, to cover sensor dies, and to cover the electrical connections made to the package substrate. The molding process can be referred to as an “encapsulation” process, although portions of the package substrates are often not covered in the mold compound during encapsulation; for example, terminals can be formed by leaving portions of conductive leads exposed from the mold compound. The terminals are configured for making electrical connections to the microelectronic device package.

The term “mold wall” is used herein. In this description, a mold wall is a structure that precludes mold compound from entering a defined area during a molding process. In the arrangements, a first molding process performed while dies are still part of a semiconductor wafer, or part of a substrate, forms mold walls that encircle a portion of a sensor die to define an open cavity for a device package. In a second molding process performed after the dies are singulated, each die having a corresponding mold wall, the mold compound in the second molding process is stopped from flowing into the area encircling the open cavity by the mold wall. In example methods for forming the arrangements, the mold walls can be formed in a transfer molding process that includes the entire wafer or substrate, so that for the dies on the wafer or substrate, a corresponding mold wall is formed over a central portion of each die.

Encapsulation often involves a transfer molding process, where a thermoset mold compound such as an epoxy resin can be used. A room temperature solid or powdered epoxy resin mold compound can be positioned in a mold tool and heated to a liquid state, and then molding can be performed by pressing the now liquid mold compound into a mold through runners or channels. Transfer molding can be used. Unit molds shaped to surround an individual device may be used, or a block molding process may be used, to form multiple packages simultaneously for several devices from mold compound. The devices to be molded can be provided in an array or matrix of several, hundreds or even thousands of devices in rows and columns on a package substrate strip or grid, the devices can then be molded contemporaneously, reducing per unit costs and increasing throughput.

In example arrangements, two different molding processes are used. A first molding process at a wafer level forms mold walls corresponding to each unit device on a substrate or wafer. After additional processing, a second molding process completes the body of a microelectronic device package. The mold walls formed in the first molding process exclude the mold compound in the second molding process from open cavities over a sensor die, the completed microelectronic device packages therefore have open cavities.

After the second molding process is complete, the individual microelectronic device packages are cut apart from each other in a sawing operation. A mechanical saw can be used to cut through the mold compound and any remaining package substrate material in saw streets that are formed between the molded devices. Portions of leads of the package substrate are exposed from the mold compound package to form terminals for the microelectronic device packages. For example arrangements packaged in leaded packages, a trim and form tool can be used to separate temporary supports, or “tie bars,” from the leads, and to form the leads into the desired shape, such as a gull-wing shape, for surface mounting to a board.

In the arrangements, during the encapsulation process using mold compound to form microelectronic device packages for sensor dies, the mold walls prevent the encapsulating mold compound from covering the open cavity defined by the mold walls. The open cavity can be circular when seen from a top view, in alternative arrangements other shapes can be used. The sensor material on the sensor dies is then exposed from the mold compound in the open cavity, and in operation, the sensor material is exposed to the atmosphere by the open cavity.

The term “scribe lane” is used herein. A scribe lane is a portion of semiconductor wafer between semiconductor dies. Sometimes in related literature the term “scribe street” is used. Once the substrate or semiconductor wafer processing is finished and the sensor dies are complete, the devices are separated into individual dies by severing the substrate or wafer along the scribe lanes. The separated dies can then be removed and handled individually for further processing. This process of removing dies from a wafer is referred to as “singulation” or sometimes referred to as “dicing.” Scribe lanes are arranged on four sides of dies and when the dies are singulated from one another, rectangular dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

After the first molding process used in the arrangements, the sensor dies along with the corresponding mold wall feature for each unit die are then singulated from the wafer or substrate to form individual sensor die units. The mold wall has a portion that defines the open cavity surrounding a portion of a sense material layer on a device side surface of the corresponding sensor die.

The sensor dies are then mounted to a device mounting portion of a package substrate, for example, a die pad of a conductive leadframe. Electrical connections can be made between bond pads of the sensor die and leads of the package substrate. In an example arrangement, wire bonds can be formed. A second molding process is then used to form a body for a microelectronic device package for each of the sensor dies. In an example, a transfer molding process with a mold tool can be used. During the second molding process, the mold wall over the device side surface of the sensor dies excludes the mold compound of the second molding process from the sensor material surrounded by the open cavity defined by the mold wall.

In contrast to prior approaches, and because the first molding process is performed while the sensor dies are still in the wafer form, the open cavities formed using methods of the arrangements are uniform in size and the thicknesses of the mold wall layer are also uniform across the units. After the sensor dies are mounted to the package substrate using a die attach material, the second molding process does not contact the sensor dies, there are no protrusions in the mold tool. A standard mold chase can be used for the second molding process, and for different sized open cavities and for different sensor die sizes. Defects due to die tilt during molding that can occur in prior approaches are greatly reduced or eliminated by use of the arrangements. A standard mold tool can be used for the second molding process, as no custom protrusions are needed to correspond to particular open cavities for the sensor dies, in contrast to the prior approaches. The use of the arrangements therefore reduces mold tool costs and reduces tooling inventory requirements for molding different devices.

Example arrangements include sensor dies with a sensor material layer. Example sensor materials include a polymer dielectric layer, a polycrystalline layer, a piezoelectric layer, a photosensitive layer, or a metal oxide layer. The sensor dies are formed so that when the sensor material layer is exposed to a condition or to a substance to be detected, an electrical change occurs in the sensor material layer. Example sensor materials useful in the arrangements include a metal oxide layer, a polymer dielectric layer, a piezoelectric layer configured for a bulk acoustic wave sensor or configured for a surface acoustic wave sensor. Example sensors that can be formed in the arrangements include a humidity sensor, a gas sensor, a temperature sensor, a moisture sensor, a pressure sensor, or a photosensor. The electrical change can be measured using electrodes coupled to or formed within the sensor material layer, and thus the physical condition or presence of the substance can be detected, or the amount of the substance can be measured. Humidity sensors can be formed using a polymer dielectric that has a dielectric constant or capacitance that changes with humidity. Alternatively, metal oxide layers can be used as humidity sensors. Metal oxide layers can also be used, for example, to detect gases such as oxidizing gases including nitrogen, and to detect reducing gases such as volatile organic compounds, for example ethanol, in an environment. Acoustic wave sensors can use crystal or polycrystalline layers to detect changes in frequency vibrations that correlate to temperature, pressure, strain, adsorption or desorption, viscosity of certain liquids, dew point or humidity. The acoustic wave sensor materials can be piezoelectric materials. Aluminum nitride can be used for acoustic wave sensor materials. Temperature sensors can include a sensor material that changes resistivity with temperature. Photodetectors can include a photosensitive sensor layer. Acoustic wave sensors can include bulk acoustic wave (“BAW”) sensors and surface acoustic wave (“SAW”) sensors. Electrodes in acoustic wave sensor material, for example aluminum nitride (AlN), can generate acoustic waves within or on the surface of the sensor material. As the sensor material is exposed to different conditions or substances, the frequency, phase, or amplitude of the acoustic waves change in predictable ways. These changes can be measured and converted into electrical signals that indicate changes in temperature, pressure, strain, or the presence of certain gases.

Methods useful for forming the arrangements include wafer scale processes for forming sensor dies in parallel, reducing costs. A substrate, which can be a silicon wafer, another type of semiconductor wafer, or a silicon dioxide (glass) or a ceramic substrate, is provided. On a device side surface, an array of sensor dies are formed. In a process useful with the arrangements, a first molding process performed on the substrate or at the wafer level forms mold walls over each of the completed sensor dies, the mold walls are shaped to define an open cavity corresponding to at least a portion of the sensor material for each of the sensor dies.

The substrate or wafer is then singulated along scribe streets between unit sensor die devices in a dicing process to separate the sensor dies one from another. Each unit sensor die has a mold wall portion overlying the sensor material on a device side surface of the sensor die.

Use of the arrangements provides an economical, wafer scale process for producing the sensor dies with the mold walls defining the open cavities and can use existing assembly equipment such as pick-and-place tools and molding tools to form an economical microelectronic device package for the sensor dies.

Use of the two step molding processes to form microelectronic device packages with open cavities advantageously results in increased uniformity in the dimensions and shapes of the open cavities, fewer defects, and less scrap, reducing per unit costs.

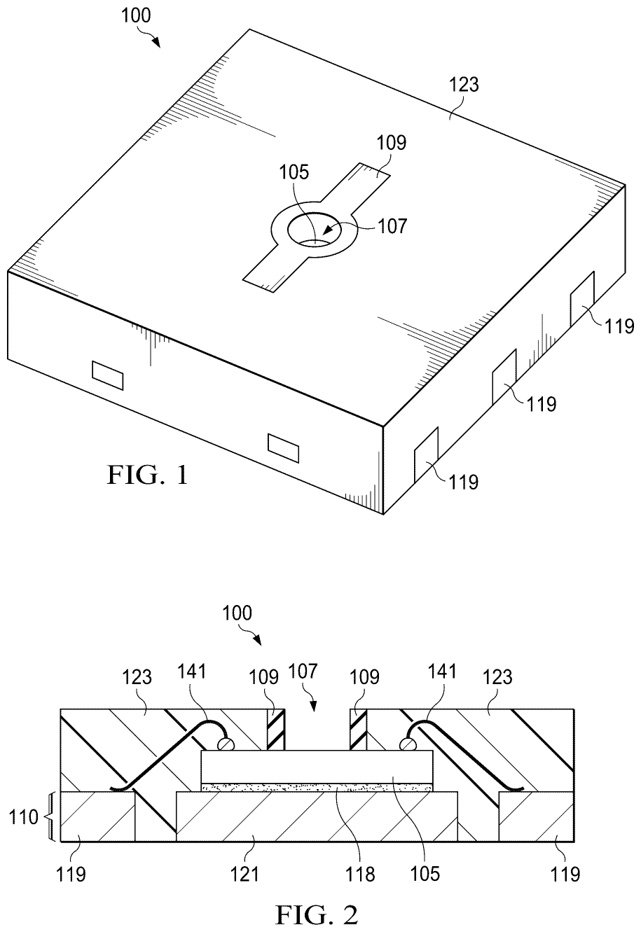

FIG. 1 illustrates, in a projection view, an example arrangement. A microelectronic device package 100 is shown with a package body formed of mold compound 123. A mold wall 109 is shown in a central portion of the microelectronic device package 100. An open cavity 107 is defined by an interior surface of the mold wall 109 and the mold wall 109 encircles a portion of the sensor die 105 (which is barely visible at the bottom of the open cavity 107 in FIG. 1.) Terminals 119 are shown along one side of the projection view, additional terminals 119 can be on the opposite side. The example microelectronic device package 100 in FIG. 1 is a “no-lead” type package, such as a quad flat no lead (“QFN”) or dual flat no lead (“DFN”) package. In alternative arrangements, other package types can be used, such as leaded packages including dual in-line package (“DIP), and small outline integrated circuit (“SOIC”) packages. The leads can be shaped as “gull wing” or “J” shapes.

FIG. 2 illustrates, in a cross-sectional view, additional details of the microelectronic device package 100. A die 105 is shown, in the arrangements die 105 is a sensor die. Die attach material 118 is used to mount the die 105 to the package substrate 110, which in the illustrated example is a leadframe. Wire bonds 141 connect bond pads of the die 105 to the package substrate 110. Mold compound 123 covers the die 105, the wire bonds 141 which form electrical connections, and portions of the package substrate 110. Mold wall 109 is shown overlying the die 105 and excludes the mold compound 123 from the open cavity 107. The package substrate 110 has leads with portions exposed from the mold compound 123 that form terminals of the microelectronic device package 100.

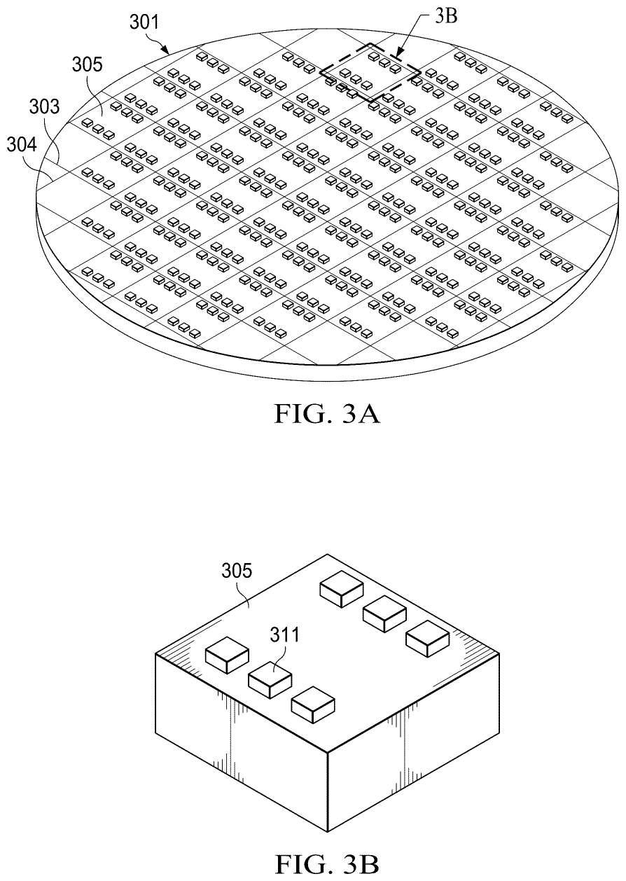

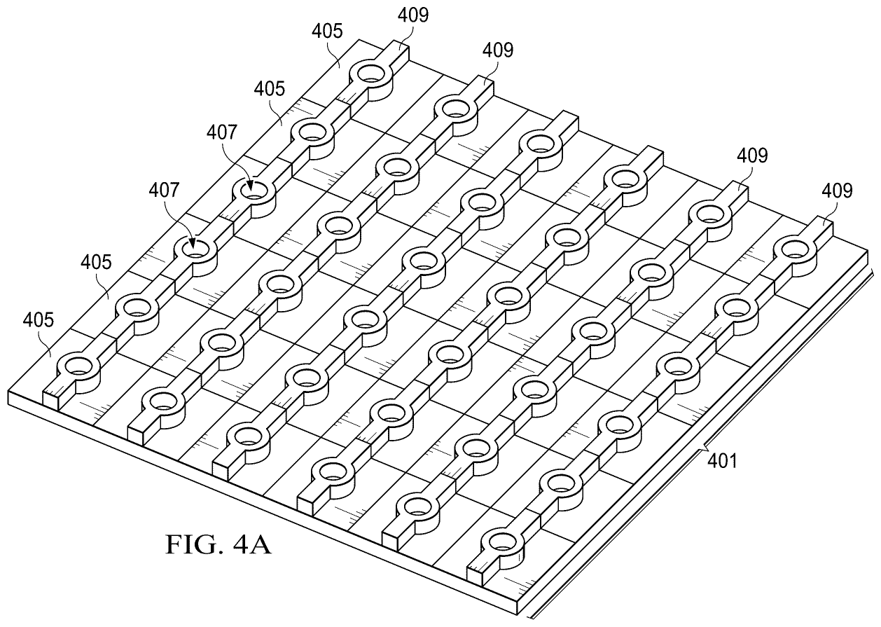

FIGS. 3A and 3B illustrate, in two projection views, a semiconductor wafer 301 having semiconductor dies 305 formed on it that are configured for wire bonding, and an individual semiconductor die 305 from the wafer 301, respectively. In FIG. 3A, semiconductor wafer 301 is shown with an array of semiconductor dies 305 formed in rows and columns on a surface. Semiconductor dies 305 can be formed using selected processes in a semiconductor wafer manufacturing facility, including ion implantation, doping, anneals, oxidation, dielectric and metal deposition, photolithography, pattern, etch, chemical mechanical polishing (CMP), electroplating, and other processes for making semiconductor devices. In FIG. 3A, scribe lanes 303 and 304, which are perpendicular to one another, and which run in parallel groups across the semiconductor wafer 301, separate the rows and columns of the completed semiconductor dies 305, and provide areas for dicing the wafer 301 to separate the semiconductor dies 305 from one another.

FIG. 3B illustrates a single semiconductor die 305 taken from semiconductor wafer 301. Semiconductor die 305 includes bond pads 311, which are conductive metal pads that are electrically coupled to devices (not shown) formed in the semiconductor die 305. Not shown for clarity of illustration are under-bump metallization (UBM) portions which can be formed over the bond pads 311 to improve plating and adhesion between the bond pads and ball bonds of bond wire to be formed on the bond pads. The semiconductor die 305 can be used in a wire bonded package, for example, by making ball bond connections on the bond pads 311.

The sensor dies can be of various sizes. In an example arrangement, the sensor dies can be of a convenient size of 300 microns×300 microns, or of a greater size. Currently, commercially available automated pick and place tools that can be used to form the arrangements have a minimum piece size requirement of about 300 microns×300 microns. As the pick and place tools evolve to allow for smaller die sizes, the sensor dies can also be made smaller. Alternatively, if other methods for moving the sensor dies onto the package substrates are used, the die sizes can be varied to be compatible with these methods. Die sizes continue to decrease as process technology continuously improves.

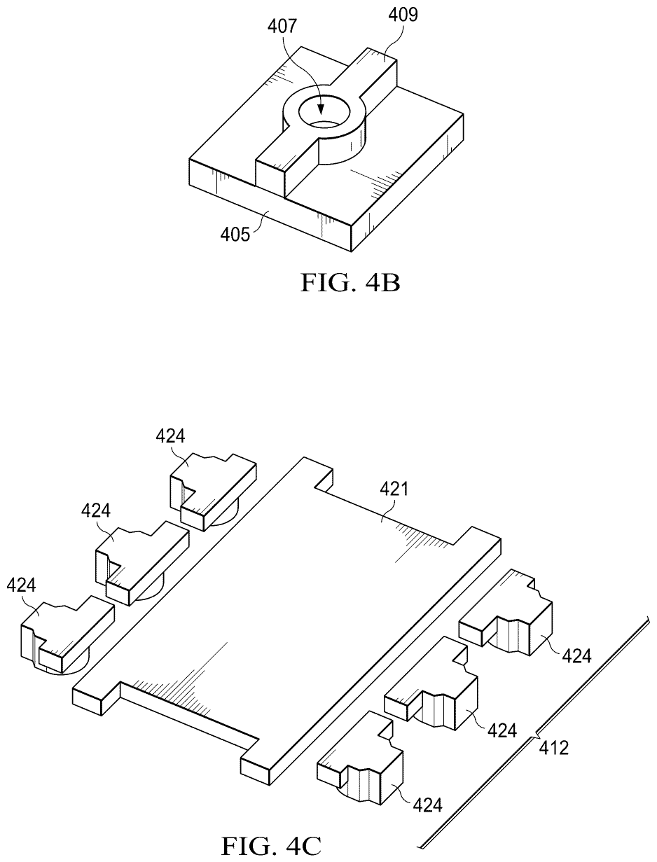

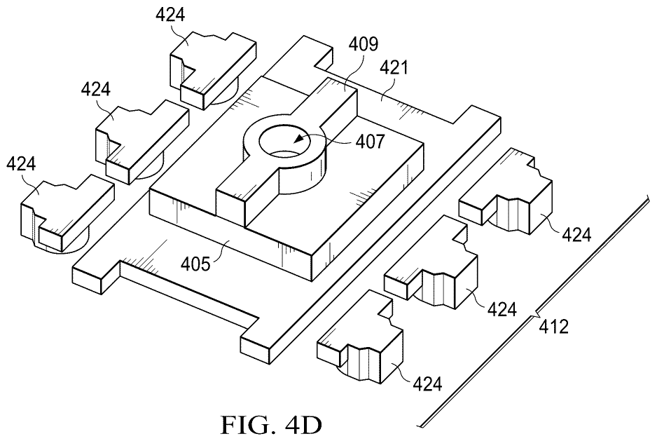

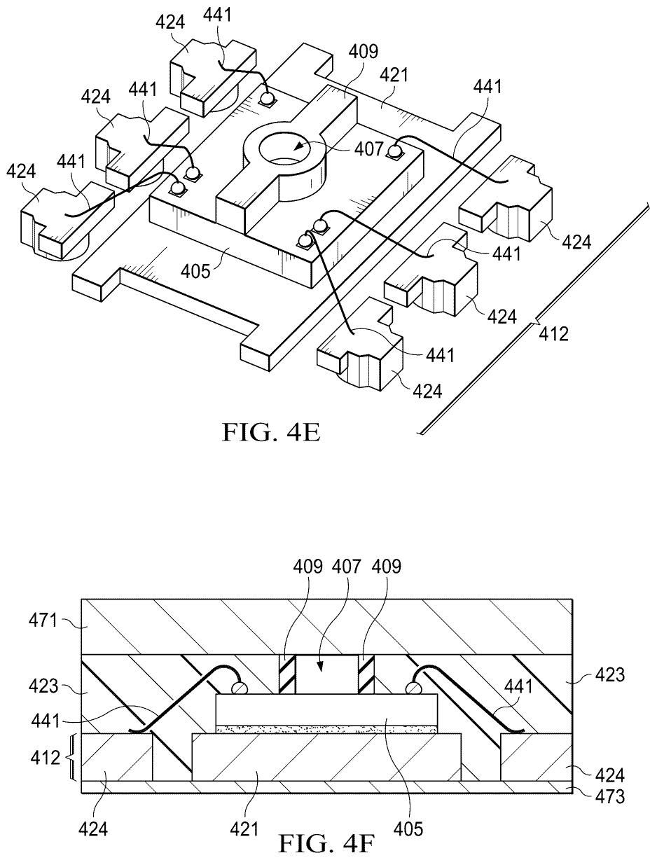

FIGS. 4A-4F illustrate, in a series of cross-sectional views, a method useful for forming a sensor die in an example arrangement. The sensor die shown in the illustrated examples is a metal oxide gas sensor. However, the methods and packages of the arrangements can be used with other types of sensor dies, in examples that can form an arrangement, a sensor material layer is formed and configured to be exposed to the ambient atmosphere to sense pressure, humidity, strain or stress, light, water, gas or liquid chemicals or concentrations.

FIG. 4A shows a substrate 401 which can be, in an example, a semiconductor wafer similar to wafer 301 in FIG. 3A. Alternatively, for certain types of sensor dies, a glass or ceramic substrate can be used, with the sensor material formed on the device side surface. Dies 405 are shown arranged in rows and columns on substrate 401.

The mold walls 409 are shown formed by a first molding process performed on the substrate 401. In an example process, an epoxy resin molding compound is used. The mold compound may be provided in a solid puck or solid powder at room temperature and then heated in a portion of the mold tool to a liquid state. The liquid mold compound can then be forced by hydraulic pressure through runners into molds that form the mold walls 409 over each of the dies 405 across the substrate 401. Because the mold walls 409 are formed while the dies 405 are still on the substrate, the dies are necessarily coplanar with respect to one another, and the resulting mold walls 409 are of uniform thickness. Also, because the dies 405 are still tied together as a substrate, there is no die tilt or movement during the mold wall molding process, and the open cavities 407 defined by the mold walls 409 are also uniform in size and shape. Epoxy resin mold compound is a thermosetting mold compound, which forms a solid after a cure process that follows the molding process.

After the molding is completed and the mold walls 409 are allowed to cure, the wafer or substrate can be thinned from the backside. In another process that is useful with the arrangements, a die attach film can be applied to the backside of the wafer or substrate 401. After the die attach film is applied and cured, a singulation step using a dicing tool, such as a mechanical dicing saw, can be used to separate the individual dies 405 and the corresponding mold wall 409 from the substrate and from each other.

FIG. 4B illustrates, in another projection view, an individual die 405 with the mold wall 409 and the cavity opening 407. In the arrangements, the die 405 is a sensor die, such as a relative humidity sensor die, a gas sensor die, or another type of sensor die as described above.

FIG. 4C illustrates, in a projection view, a package substrate 412. In the illustrated example of FIGS. 4A-4F, the package substrate 412 is a conductive leadframe. In an example useful with the arrangements, a copper leadframe can be used, other leadframes such as steel, stainless steel, or Alloy 42 can be used. A device mounting surface 421, in this example a die pad of the leadframe, is shown spaced from the leads 424. Leads 424 will provide conductive lands for electrical connection to a die to be mounted on the package substrate, and a portion of the leads 424 will be exposed from the package body in a later step, and the exposed portions can form terminals for the microelectronic device package.

While in FIG. 4C a single package substrate 412 is shown for ease of illustration, in a production example the package substrates will be provided in a grid or array of unit package substrates that are temporarily connected for processing, and which support the dies during die mounting, wire bonding, molding and singulation steps, for example when using a leadframe such as shown in FIG. 4C for a package substrate, tie bars (that are later cut apart) are used to temporarily connect the individual package substrates into a strip, array or grid.

FIG. 4D illustrates the package substrate 412 of FIG. 4C after a die mounting process mounts die 405 to the die pad 421. In an example process, a die attach film is attached to the backside of the die 405 while the die 405 is still attached to a semiconductor wafer or other substrate as described above. In alternative approaches that can be used with the arrangements, die attach epoxy is dispensed onto the die pad 421 prior to the die mounting process. Conductive die attach film can be used when an electrical connection to the die pad 421 is needed. In other applications, a non-conductive die attach film or non-conductive die attach material can be used to electrically isolate the die 405 from the die pad 421.

FIG. 4E illustrates, in a further projection view, the elements of FIG. 4D after an additional process. In FIG. 4E, electrical connections are made between the die 405 and the leads 424. In the illustrated examples, wire bonds 441 are formed using a wire bonding tool. Wire bonds 441 are made connecting bond pads (not shown in FIG. 4E for simplicity of illustration) of the die 405 to the leads 424. In alternative processes also useful with the arrangements, ribbon bonds can be used.

In an example wire bonding process useful with the arrangements, an automated wire bonder is used. The bond wire used can be any bond wire used in semiconductor packaging, such as copper, copper alloy, gold, aluminum, or silver. Copper bond wires are often used. Palladium coated copper (“PCC”) bond wires can be used, When copper or coated copper bond wires are used in a wire bonder, an anoxic atmosphere may be used to prevent unwanted tarnish and oxidation of the bond wires, processes that can be accelerated by the elevated temperatures used in wire bonding. For example, nitrogen can be used to provide an anoxic environment during wire bonding processes.

In one process useful with the arrangements, a “ball and stitch” wire bonding process is used. The wire bonding tool has a capillary with a central opening. The capillary can be of hard material such as a ceramic. The bond wire is allowed to extend from a central opening in a capillary of the bonding tool. A supply of bond wire can be provided from a spool coupled to the capillary, for example. The bonding tool can have clamps attached to or operated in correspondence with the capillary, the clamps can be used to selectively pull and shape the wire to form wire bonds that arc over the dies. The capillary is configured to move in “X” and “Y” directions in a horizontal plane, and to move vertically in the “Z” direction relative to the package substrates. The wire bonding tool can move either the capillary, the package substrate, or both to achieve the necessary movements in three directions.

To begin a wire bonding cycle, the bond wire is allowed to extend a short distance through a central opening of the capillary. A molten ball is formed on the exposed end of the bond wire using an electronic arc or a flame. The capillary then moves over a bond pad of the die, and mechanical, thermal, and sonic energy are applied to bond the molten ball to the bond pad, forming a ball bond on the bond pad. Wire bonders that use sonic energy in conjunction with thermal energy can be referred to as performing “thermosonic” wire bonding.

After the ball bond is formed on the bond pad, the capillary moves away from the bond pad while allowing the bond wire to extend from the ball bond. The capillary moves to a position over a lead where a wire bond is to be formed. The capillary then presses the bond wire onto the lead, and again using the sonic energy and mechanical pressure, a stitch bond is formed. After the stitch bond is formed, the capillary moves a short distance from the stitch bond, and the bond wire is broken or cut. A short tail can be left extending from the stitch bond. This process is sometimes referred to as “ball and stitch” wire bonding.

Alternative bonding processes include standoff stitch bonding (“SSB”) wire bonding. In this approach, a ball is formed using the molten ball on the bond wire at a first location to form a bump, for example the bump can be formed on a lead. The capillary then moves away from the bump and forms another molten ball. The process then continues as in the ball and stitch process, the ending stitch is now formed on the original bump, so that the stitch is formed on the standoff bump.

An automated wire bonding tool can perform tens or hundreds of these wire bonds per minute and can be programmed to quickly form the wire bonds needed for the sensor dies very efficiently. While wire bonding is one example of an electrical connection that is useful with the arrangements, ribbon bonding can also be used. In ribbon bonding, a solid ribbon conductor can be placed instead of bond wire.

FIG. 4E shows wire bonds 441 made between the semiconductor die 405 and leads 424 of the package substrate 412, a conductive leadframe. The bond wire used in an example useful with the arrangements is a copper bond wire.

FIG. 4F illustrates, in a cross-sectional view, the elements of FIG. 4E including package substrate 412, the die 405 and the wire bonds 441, during a transfer molding process in a mold tool. An upper surface 471 of the mold tool overlies and covers the open cavity 407, and with the mold wall 409, excludes mold compound 423 from the open cavity 407, exposing the device side surface of the sensor die 405 from a package body being formed during the molding process. A support surface 473 that is on the board side of the package substrate 412 prevents the mold compound 423 from covering the board side of the leads 424 and the die pad 421, these exposed portions of the leads forming terminals and a thermal pad for the package body being formed.

In a molding process useful with the arrangements, the mold compound 423 can be formed of electronic mold compound (“EMC”). EMC is a thermosetting epoxy resin with fine filler particles used for many electronic device packages. The use of the filler particles, which are thermally conductive, improves the thermal dissipation, and adds mechanical strength, to the finished package. Epoxy, resin, plastic, or thermoplastic materials can also be used as alternatives to the mold compound to form the package body. EMC is commercially available from many suppliers, including Kyocera Corporation of Tokyo, Japan.

During the molding process, use of the arrangements eliminates the need for protrusions in the mold tool and eliminates the need for custom mold tooling for forming the open cavity 407 during the encapsulation molding process. Standard mold tools can be used, and the same molds can be used for a variety of open cavity packages without modification. Because the device side surface of the die 405 is not contacted by the mold tool during the encapsulation process, the problems with die tilt and possible die cracking associated with the prior approaches to forming an open cavity package are greatly reduced or eliminated, at relatively low cost.

After the encapsulation molding process is completed, the completed packaged devices can be cut from one another, and the result is a microelectronic device package with an open cavity encircled by a mold wall, see for example microelectronic device package 100 as shown in FIGS. 1-2. In an alternative, the package substrate 412 can be a laminate or multilayer package substrate, such as a build-up package substrate.

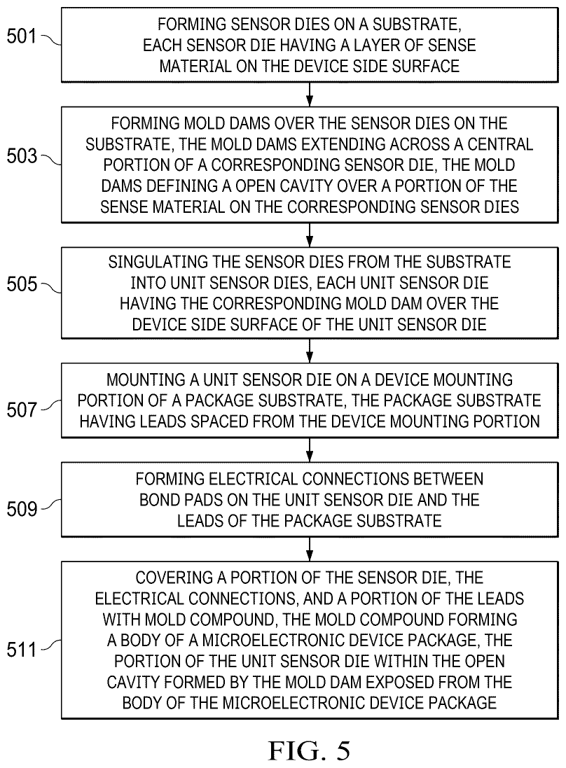

FIG. 5 illustrates, in a flow diagram, selected steps of a method used to form a microelectronic device package of an arrangement.

At step 501, the method begins by forming sensor dies on a substrate, each sensor die having a layer of sense material on a device side surface. (See, for example, FIG. 4A, dies 405 on substrate 401, and see sensor die 405 in FIG. 4B).

At step 503, the method continues by forming mold walls over the sensor dies on the substrate, the mold walls extending across a central portion of a corresponding sensor die, the mold walls defining an open cavity over a portion of the sense material on the corresponding sensor dies. (See, for example, FIG. 4A, mold walls 409 on the sensor dies 405, defining the open cavities 407, and see FIG. 4B, the individual sensor die 405 has mold wall 409 and open cavity 407).

At step 505, the method continues by singulating the sensor dies from the substrate into unit sensor dies, each unit sensor die having the corresponding mold wall over the device side surface of the unit sensor die. (See, for example FIG. 4B, the sensor die 405 with mold wall 409 and open cavity 407).

At step 507, the method continues by mounting a unit sensor die on a device mounting portion of a package substrate, the package substrate having leads spaced from the device mounting portion. (See, for example, FIG. 4D, with the unit sensor die 405 mounted on the package substrate 412),

At step 509, electrical connections are formed between bond pads on the unit sensor die and the leads of the package substrate. (See, for example, FIG. 4E, the wire bonds 441 are electrical connections between bond pads on sensor die 405 and the leads of the package substrate).

At step 511 the method completes by covering a portion of the sensor die, the electrical connections, and a portion of the leads with mold compound, the mold compound forming a body of a microelectronic device package, the portion of the unit sensor die within the open cavity formed by the mold wall exposed from the body of the microelectronic device package. (See, for example, FIG. 4F, where mold compound 423 is shown forming the body of the microelectronic device package, see also FIGS. 1A-1B, where the mold compound 123 is shown forming the body of the microelectronic device package 100. The mold wall 409 prevents the mold compound from covering the open cavity 407 during the molding process as shown in FIG. 4F).

Use of the arrangements advantageously provides an open cavity microelectronic device package for use with sensor dies at a low cost, and without the defects that can occur using prior approaches. The use of the first molding process to form the mold walls at the wafer level allows the mold walls to be formed in a gang process while the dies are still part of the substrate, and the dies therefore are not subject to die tilt or die cracking defects that can occur when the prior approaches are used. In the mold encapsulation process, the mold tools and molds can be standardized without the need for protrusions or film assisted molding to form the open cavities, reducing costs, and reducing the need to inventory customized molds for different sensor die products.

Modifications are possible in the described arrangements, and other alternative arrangements are possible within the scope of the claims.

What is claimed is:

1. A method, comprising:
forming sensor dies on a substrate, each sensor die having a layer of sense material on a device side surface;
forming mold walls over the sensor dies on the substrate, the mold walls extending across a central portion of a corresponding sensor die, the mold walls defining an open cavity over a portion of the sense material on the corresponding sensor dies;
singulating the sensor dies from the substrate into unit sensor dies, each unit sensor die having a corresponding mold wall defining an open cavity over the device side surface of the unit sensor die;
mounting a unit sensor die on a device mounting portion of a package substrate, the package substrate having leads spaced from the device mounting portion;
forming electrical connections between bond pads on the unit sensor die and the leads of the package substrate; and
covering a portion of the unit sensor die, the electrical connections, and a portion of the leads with mold compound, the mold compound forming a body of a microelectronic device package, the portion of the unit sensor die within the open cavity defined by the mold wall exposed from the body of the microelectronic device package.

2. The method of claim 1, wherein the open cavity defined by the mold wall exposed from the body of the microelectronic device package exposes the layer of sense material on the unit sensor die to the atmosphere.

3. The method of claim 1, wherein forming the mold walls further comprises performing a transfer molding process using thermoset mold compound.

4. The method of claim 3, wherein the layer of sense material further comprises a metal oxide layer of tin oxide, zinc oxide, titanium oxide or cobalt oxide.

5. The method of claim 3, wherein the layer of sense material further comprises a polyimide with a dielectric constant that varies with changes in relative humidity or a layer of aluminum nitride.

6. The method of claim 1, wherein the layer of sense material further comprises a metal oxide layer, a polymer dielectric layer, a piezoelectric layer configured for a bulk acoustic wave sensor, or a piezoelectric layer configured for a surface acoustic wave sensor.

7. The method of claim 1, wherein mounting the sensor die on a device mounting surface of a package substrate further comprises mounting a backside surface of the sensor die on a die pad of the package substrate, the die pad spaced from the leads.

8. The method of claim 7, wherein forming electrical connections between the bond pads on the sensor die and the leads further comprises forming wire bonds.

9. A method, comprising:
forming sensor dies on a substrate, the sensor dies comprising a polymer dielectric on a device side surface of the sense dies;
forming mold walls over the sensor dies on the substrate, the mold walls extending across a central portion of corresponding sensor dies, the mold walls defining open cavities over a portion of the polymer dielectric material on the corresponding sensor dies;
singulating the sensor dies from the substrate into unit sensor dies, each unit sensor die having a corresponding mold wall over the device side surface of the unit sensor die;
mounting a unit sensor die on a die pad of a leadframe, the leadframe having leads spaced from the die pad;
forming wire bonds between bond pads on the unit sensor die and the leads of the package substrate; and
covering a portion of the unit sensor die, the wire bonds, and a portion of the leads with mold compound, the mold compound forming a body of a microelectronic device package, the portion of the unit sensor die within the open cavity defined by the mold wall exposed from the body of the microelectronic device package.

10. The method of claim 9, wherein the unit sensor die comprises a relative humidity sensor.

11. The method of claim 9, wherein forming the mold walls over the device side surface of the sensor dies further comprises:
placing the substrate in a mold tool; and
flowing liquid resin epoxy mold compound over the substrate, the mold tool having molds that form the mold walls with circular portions over a central portion of the sensor dies, the circular portions of the mold walls defining the open cavities.

12. The method of claim 9, wherein the open cavity in the microelectronic device package faces away from a board side of the microelectronic device package.

13. An apparatus, comprising:
a sensor die having a layer of sense material on a device side surface, and having bond pads on the device side surface;
a mold wall formed over a central portion of the device side surface, the mold wall defining an open cavity over a portion of the sense material;
the sensor die mounted on a device mounting surface of a package substrate, the package substrate having leads spaced from the device mounting surface;
electrical connections coupling bond pads of the sensor die to the leads of the package substrate; and
mold compound covering a portion of the sensor die, the electrical connections, and a portion of the leads, the mold compound forming a body of a microelectronic device package, wherein the portion of the sensor die within the open cavity defined formed by the mold wall is exposed from the body of the microelectronic device package.

14. The apparatus of claim 13, wherein the package substrate comprises a leadframe and the device mounting surface comprises a die pad of the leadframe.

15. The apparatus of claim 13, wherein the electrical connections comprise wire bonds.

16. The apparatus of claim 13, wherein the layer of sense material further comprises a metal oxide layer, a polymer dielectric layer, a piezoelectric layer configured for a bulk acoustic wave sensor, or a piezoelectric layer configured for a surface acoustic wave sensor.

17. A microelectronic device package with an open cavity, comprising:
a sensor die having a layer of sense material on a device side surface;
a mold wall formed over a central portion of the device side surface of the sensor die, the mold wall defining the open cavity over a portion of the sense material;
the sensor die mounted on a die pad of a leadframe having leads spaced from the die pad;
wire bond connections formed between the bond pads of the sensor die and the leads of the leadframe; and
mold compound covering a portion of the sensor die, the wire bonds, and a portion of the leads, the mold compound forming the body of the microelectronic device package, wherein the portion of the sensor die within the open cavity defined by the mold wall is exposed from the body of the microelectronic device package.

18. The microelectronic device package with an open cavity of claim 17, wherein the mold wall comprises a thermoset mold compound.

19. The microelectronic device package with an open cavity of claim 17, wherein the sensor die further comprises: a humidity sensor, a gas sensor, a temperature sensor, a moisture sensor, a pressure sensor, or a photosensor.

20. The microelectronic device package with an open cavity of claim 17, wherein the sense material further comprises: a metal oxide layer, a polymer dielectric layer, a piezoelectric layer configured for a bulk acoustic wave sensor or configured for a surface acoustic wave sensor.
